(19) United States
(12) Patent Application Publication
(10) Pub. No.: US 2025/0260408 A1
(43) Pub. Date: Aug. 14, 2025

(54) PHASE NOISE CANCELLING PHASE LOCKED LOOP (PLL)

(71) Applicant: ARIZONA BOARD OF REGENTS ON BEHALF OF ARIZONA STATE UNIVERSITY, Scottsdale, AZ (US)

(72) Inventors: Saeed ZEINOLABEDINZADEH, Chandler, AZ (US); Waleed Ahmad, Tempe, AZ (US)

(73) Assignee: ARIZONA BOARD OF REGENTS ON BEHALF OF ARIZONA STATE UNIVERSITY, Scottsdale, AZ (US)

(21) Appl. No.: 19/048,406

(22) Filed: Feb. 7, 2025

Related U.S. Application Data
(60) Provisional application No. 63/551,898, filed on Feb. 9, 2024.

(51) Int. Cl. H03L 7/099; H03L 7/083; H03L 7/093

(52) U.S. Cl. CPC H03L 7/0992; H03L 7/083; H03L 7/093

(57) ABSTRACT

A phase noise cancellation technique to reduce phase noise and improve timing stability in a variety of electronic devices. The system and method include two phase locked loops (PLLs) in a cascaded configuration. The second PLL is used as a buffer to collect the replicated correlated phase noise which is then used in a feedback circuit to cancel out the original phase noise on the first PLL.

### CROSS REFERENCE TO RELATED APPLICATIONS

This application claims the benefit of U.S. Provisional Patent Application No. 63/551,898 filed on Feb. 9, 2024, the contents of which are hereby incorporated by reference in its entirety.

### GOVERNMENT FUNDING

This invention was made with government support under HR0011-20-1-0012 awarded by DARPA (Defense Advanced Research Projects Agency) and under N00014-21-1-2897 awarded by the Office of Naval Research. The government has certain rights in the invention.

### TECHNICAL FIELD

The present disclosure relates to reducing phase noise and jitter in timing reference signals to improve, for example, but not limited to, electronic devices.

### BACKGROUND

The short-term stability of timing reference signals plays a critical role in the proper operation of variety of electronic devices that use clocks and frequency synthesis. For wireless and wireline communication applications, short-term clock stability is a main concern that is not generally accounted for by periodic synchronizations between the radio nodes. Short-term clock stability is especially critical for RF applications and is mostly influenced by the clock's phase noise. Phase noise is the random fluctuation in the phase of the reference signals. Phase noise is also referred to as timing jitter when timing replaces phase as the parameter of choice. Phase noise impacts, for example, but not limited to, signal-to-noise ratio (SNR), ranging accuracy, error vector magnitude (EVM), and effective number of bits (ENoB) for high-speed data conversion.

A conventional methodology to synthesize the frequencies uses a frequency synthesizer circuit and/or a phased locked loop (PLL) circuit. This type of circuit uses a servo loop to electronically force the signal generator to follow the stability of the reference clock signal. The phase-noise response of such a frequency synthesizer or phase locked loop (PLL) has two main contributing components that define the signals' phase-noise spectrum, the close-in phase-noise spectrum and the far-end phase noise spectrum. The close-in phase-noise spectrum is, for the most part, determined by the input reference signal's phase noise. The far-end phase noise, where the synthesizer or PLL loop cannot follow up with the changes, follows the local voltage-controlled oscillator (VCO)'s phase noise. Improving the contributing signals' phase noise (i.e., reference and local VCO) can improve the phase noise of the synthesized signal. Signal purity, i.e., phase noise, is often limited by the quality of the passive components used in VCO circuits such as capacitors, inductors, or any other type of resonators. To improve the phase noise of signals, techniques such as phase-noise cancellation through a delay-line discriminator are used. These techniques, however, require a delay-line discriminator that can either be unfeasibly bulky or contribute to phase noise when implemented using active circuits. Instead, a phase-noise cancellation technique that does not require a delay-line discriminator can be used. A phase-noise cancellation and improvement technique can significantly improve clock stability, reduce phase noise, and improve timing stability.

### SUMMARY

Embodiments of the system and method in accordance with the present disclosure can be used in either of these PLL or frequency synthesizer topology. Frequency synthesis has been performed using a phase locked loop (PLL) to lock the phase of a locally generated, low-quality signal to a stable reference clock that operates at lower frequencies. A more generalized PLL is a frequency synthesizer circuit where the locally generated signal is locked to a lower frequency reference and generates signals with programmable frequencies. An architecture in accordance with embodiments of the present disclosure provides phase noise cancellation to improve the signal stability and phase noise. The system and method of the present disclosure require no delay lines and minimize noise from the analog components used in traditional systems.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method for cancelling phase noise. The method includes selecting a first bandwidth and a first voltage-controlled oscillator (VCO) for a first PLL, selecting a second bandwidth and a second VCO for a second PLL, and supplying a reference signal and a first frequency divider signal as input to the first PLL. An output from the first PLL is an input to a first frequency divider, and the first frequency divider produce the first frequency divider signal. The method includes supplying the first frequency divider signal as the reference signal to the second PLL and a second frequency divider signal as input to the second PLL. An output from the second PLL is the input to a second frequency divider. The second frequency divider produces the second frequency divider signal. The method includes cancelling the phase noise on a control line of the first VCO by subtracting a weighted amplified correlated noise voltage of a control node of the second VCO from a noise voltage of the control node of the first VCO after amplification by an amplifier. Other embodiments of this aspect include corresponding computer systems, apparatus, and computer programs recorded on one or more computer storage devices, each configured to perform the actions of the methods.

One general aspect includes a method for cancelling noise in a first PLL. The method includes using a second PLL as a buffer to the first PLL, collecting replicated correlated noise from the second PLL, and using a feedback circuit to cancel the noise of the first PLL. Other embodiments of this aspect include corresponding computer systems, apparatus, and computer programs recorded on one or more computer storage devices, each configured to perform the actions of the methods.

One general aspect includes a system for cancelling phase noise. The system includes a first PLL that has a first pre-selected bandwidth. The first PLL receives a reference signal, and the first PLL has a first VCO. The system also includes a second PLL that has a second pre-selected bandwidth. The second PLL has a second VCO. The system includes a first frequency divider that supplies a first frequency divider signal as an input signal to the first PLL and the reference signal to the second PLL. The first frequency divider receives an output signal from the first PLL as the input signal to the first frequency divider. The system includes a second frequency divider that receives an output from the second PLL and supplies a second frequency divider signal to the second PLL. The phase noise is cancelled on a control line of the first VCO by subtracting a correlated noise voltage of a control node of the second VCO from a noise voltage of the control node of the first VCO. The correlated noise voltage of the control node of the second VCO is amplified. Other embodiments of this aspect include corresponding computer systems, apparatus, and computer programs recorded on one or more computer storage devices, each configured to perform the actions of the methods.

### BRIEF DESCRIPTION OF THE DRAWINGS

The subject matter of the present disclosure is particularly pointed out and distinctly claimed in the concluding portion of the specification. A more complete understanding of the present disclosure, however, may be obtained by referring to the detailed description and claims when considered in connection with the drawing figures, wherein like numerals denote like elements.

FIG. 1 is a schematic block diagram of the phase noise cancellation topology in accordance with embodiments of the present disclosure;

FIGS. 2A-2E are circuit diagrams of exemplary circuits in accordance with embodiments of the present disclosure;

FIG. 3A is a graphical representation of a simulated transfer function from the noise sources to the output of the PLL before and after noise cancellation;

FIG. 3B is a graphical representation of simulated phase noise;

FIG. 4 is a flowchart of a first method in accordance with embodiments of the present disclosure; and

FIG. 5 is a flowchart of a second method in accordance with embodiments of the present disclosure.

### DETAILED DESCRIPTION

The detailed description of various embodiments herein makes reference to the accompanying drawings and pictures, which show various embodiments by way of illustration. While these various embodiments are described in sufficient detail to enable those skilled in the art to practice the disclosure, it should be understood that other embodiments may be realized and that logical and mechanical changes may be made without departing from the spirit and scope of the disclosure. Thus, the detailed description herein is presented for purposes of illustration only and not of limitation. For example, the steps recited in any of the method or process descriptions may be executed in any order and are not limited to the order presented. Moreover, any of the functions or steps may be outsourced to or performed by one or more third parties. Furthermore, any reference to singular includes plural embodiments, and any reference to more than one component may include a singular embodiment.

A PLL circuit is a feedback loop that includes a VCO, a phase detector (PFD), and a low pass filter (LPF). The purpose of the PLL circuit is to force the VCO to replicate and track the frequency and phase at the input when in lock. A frequency synthesizer uses a reference frequency to generate a multiple of that frequency, whereas the PLL locks the VCO to the same reference frequency. A VCO is initially tuned roughly to the range of the desired frequency multiple. The signal from the VCO is divided down using frequency dividers. The division ratio is the same as the multiplication factor to generate the output frequency from a lower frequency reference. Two PLLs can be cascaded. The purpose of cascaded PLLs is to purify the input reference signal by filtering the phase noise of the reference signal when the far-end phase noise of the signal from the VCO of a first PLL is superior to the input reference of the first PLL. The second PLL receives the input from the first PLL as a reference signal. The phase noise cancellation in the present disclosure uses cascaded PLLs as the body of the phase locking and uses a technique to perform the phase noise cancellation. In the cascaded PLLs, the second PLL follows the phase noise response of the first PLL within the bandwidth of the PLL. The noise at the control node of the second VCO appears as a correlated and approximate replica of the noise appearing on the control node of the first VCO within the PLL loop bandwidth. Embodiments in accordance with the present disclosure use direct noise cancellation at the control nodes to purify the phase noise at the output of the system.

In the cascaded PLL configuration, the first PLL loop is designed for a relatively low bandwidth, whereas the second PLL loop is designed to provide a relatively larger bandwidth. The PLL bandwidth is associated with PLL loop characteristics such as phase locking speed, stability, and phase noise shaping. In some configurations, the relatively small bandwidth of the first PLL cannot filter the far-end phase noise of the reference.

In embodiments in accordance with the present disclosure, the first PLL is not required to have a relatively small bandwidth because the signal phase noise from the output signal is improved through a phase-noise cancellation mechanism. In embodiments in accordance with the present disclosure, the bandwidth of the PLL circuits is chosen arbitrarily, depending upon the quality of the reference and the VCO in the first PLL, and on the application. The bandwidth choice of the second PLL can impact the bandwidth of the phase-noise cancellation mechanism. The larger the bandwidth of the second PLL, the wider the noise cancellation bandwidth. The bandwidth choice of the first PLL may have a smaller or no impact on the bandwidth of the phase-noise cancellation process. The phase noise cancellation circuit, in accordance with embodiments of the present disclosure, utilizes the second PLL as a buffer to the first PLL in the phase domain. The phase noise cancellation circuit collects the replicated correlated phase noise from the second PLL and utilizes a feedback circuit to cancel out the original phase noise of the first PLL. The first PLL's output phase noise contains two separate spectra. The close-in phase noise is dictated by the reference signal, while the far-end phase noise is dictated by the first VCO. Due to the operation of the PLL and regardless of the phase noise origin, a noise voltage appears on the control node of the first VCO. Also, the noise voltage translates to the observed phase noise at the output of the first VCO and the first PLL as a result of the feedback in the PLL circuit. The second PLL directly follows the first PLL's output within the bandwidth of second PLL, which is applied as a reference to the second PLL. If the other noise contributors in the circuit have significantly smaller contributions, the output phase noise from the second PLL is correlated to the phase noise of the first PLL, and represents a replica phase noise characteristic. Further, the control node of the second VCO includes a correlated noise voltage that appears on the control node of the first VCO. Therefore, the correlated noise voltage of the control node of the second VCO can be subtracted at the first PLL control node from the noise voltage of the control node of the first VCO, thus canceling the noise on the control line of the first VCO, thus the resultant phase noise at the output of that VCO and accordingly the second VCO which follows the first PLL within the bandwidth of the second PLL.

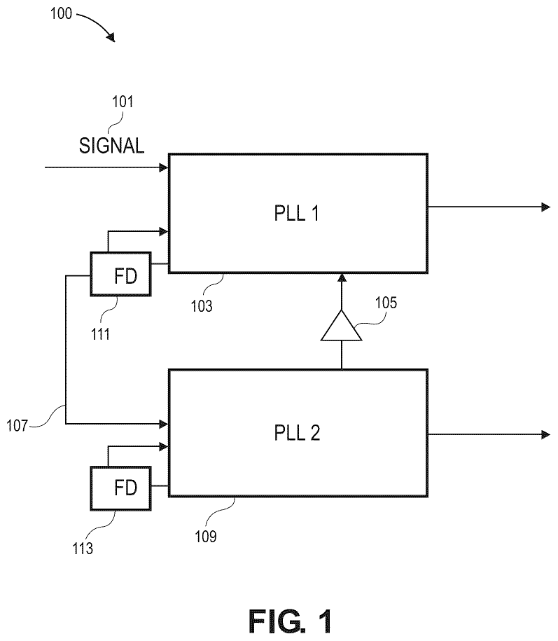

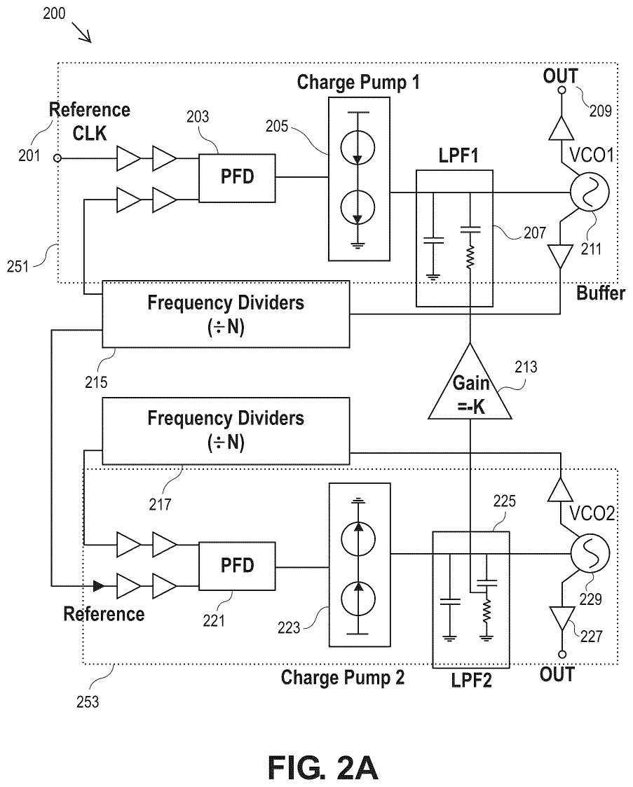

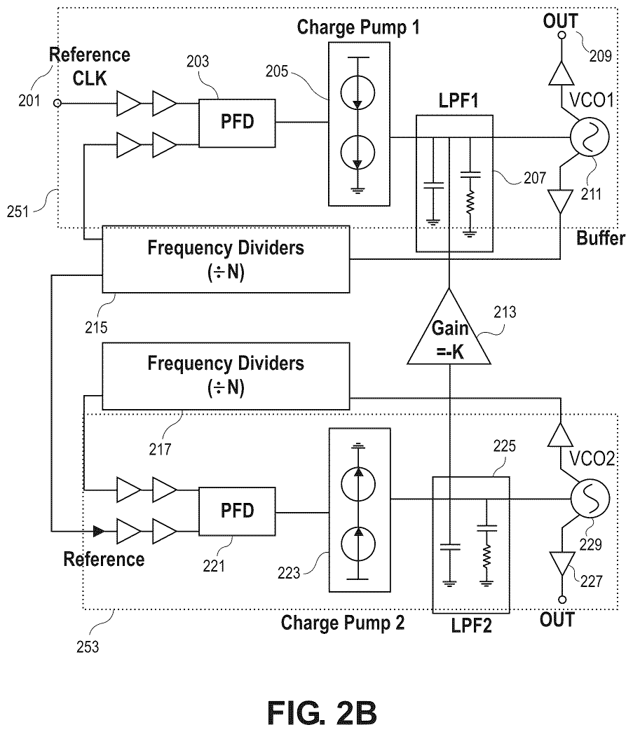

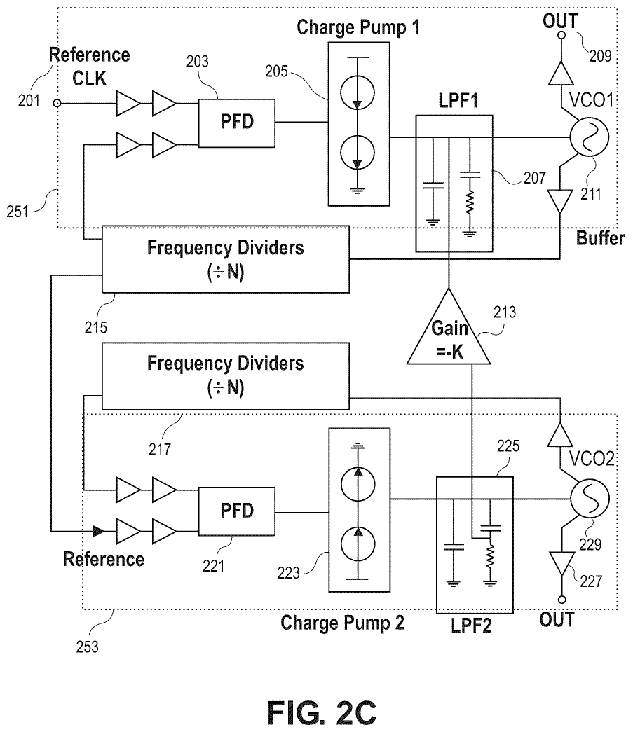

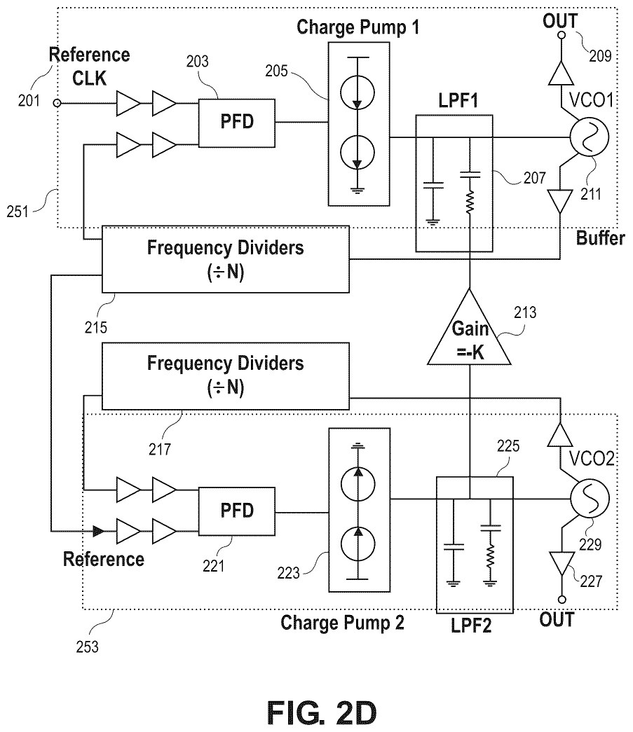

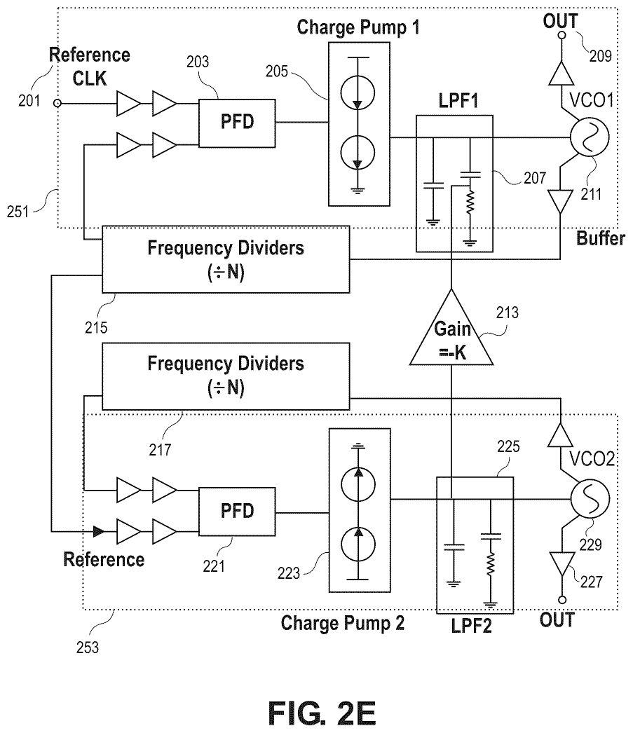

Referring now to FIG. 1, shown is a schematic block diagram of the phase-noise cancellation system in accordance with embodiments of the present disclosure. The noise cancellation system 100 includes two PLL circuits 103 and 109, similar to cascaded PLLs. PLL 103 receives as input a reference signal 101 and a signal from a frequency divider 111. Output from PLL 103 is also provided to the frequency divider 111. The PLL 109 receives as input the output signal from the frequency divider 111 and the output signal from the frequency divider 113. Gain 105 is applied to the signal in the PLL 103 based on the signal in the PLL 109. The gain factor is variable and affects the amount of phase noise improvement and stability of the PLL. The default value is −15 for the amplifier in FIG. 2A. The amplifier has the frequency bandwidth higher than the loop bandwidth of the second PLL and the phase noise contribution of the amplifier is lower than the phase noise improvement in the PLL. The output from the PLL 109 is also provided to the frequency divider 113, thus forming a feedback loop to cancel the phase noise from the PLL 103.

Referring now to FIGS. 2A-2E, exemplary circuits in accordance with embodiments of the present disclosure are shown. In operation, a reference signal 201 is provided to a first PLL 251. The first PLL 251 includes a phase frequency detector (PFD) 203 that receives as input the reference signal 201 and a signal from a first frequency divider 215. The PFD 203, when used in a PLL application, can enable lock to be achieved even when the two signals being compared differ not only in phase but in frequency. The PFD 203 can prevent the condition in which the PLL synchronizes with the wrong phase of the input signal or with the wrong frequency. The first PLL 251 also includes a charge pump circuit 205 that supplies charge amounts to the VCO 211 in proportion to the phase error detected by the PFD 203. The current output from the charge pump circuit 205 is fed to the LPF 207. The LPF 207 extracts the average of the phase detector error pulses in order to produce the control voltage for the VCO 211. The LPF 207 ensures that the DC control voltage from the charge pump 205 changes gradually when fed to the VCO 211 to avoid abrupt frequency shifts in the VCO output signal 209.

Continuing to refer to FIGS. 2A-2E, the LPF 207 includes capacitors and a resistor. The loop filter is designed together with other loop parameters for the desired loop bandwidth, stability, and phase noise (jitter in time domain). The second capacitor can smooth the ripple of the control voltage. Output from the VCO 211 is fed back into the frequency divider 215. PLLs make use of frequency dividers to divide down the VCO frequency to the vicinity of the reference frequency for a meaningful comparison with the reference frequency. The signal generated by the frequency divider 215 is provided as the reference input to the second PLL 253 to be compared with the signal generated by the frequency divider 217 which is the divided frequency of the second VCO 229, the comparison is done in PFD 221 which provides a signal to the charge pump 223. The charge pump 223 supplies charge amounts to the VCO 229 in proportion to the phase error detected by the PFD 221. The current output from the charge pump circuit 223 is fed to the LPF 225. The LPF 225 extracts the average of the phase detector error pulses in order to produce the control voltage for the VCO 229. The LPF 225 ensures that the DC control voltage from the charge pump 223 changes gradually when fed to the VCO 229 to allow time for the VCO 229 and the entire loop to settle in a stable form.

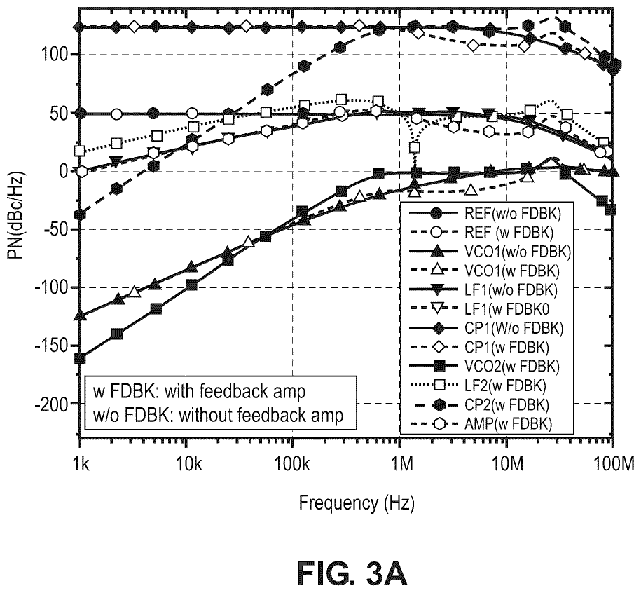

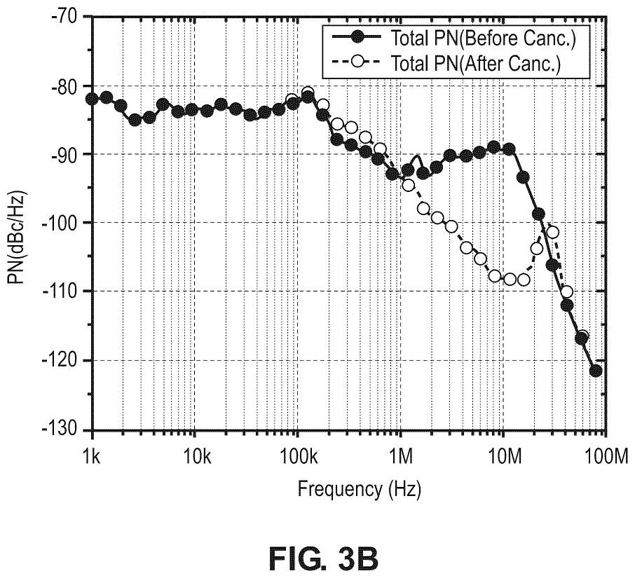

Referring now to FIGS. 3A and 3B, the simulated transfer function characteristics from the dominant noise sources to the PLL output are shown before and after introducing the noise cancellation system and method and the output phase noise for the embodiment in FIG. 2A. The PLL phase noise is shown to be filtered. Thus, the amount of phase noise at the PLL's output is reduced. It should be noted that embodiments in accordance with the present disclosure are independent of the type of VCO circuit.

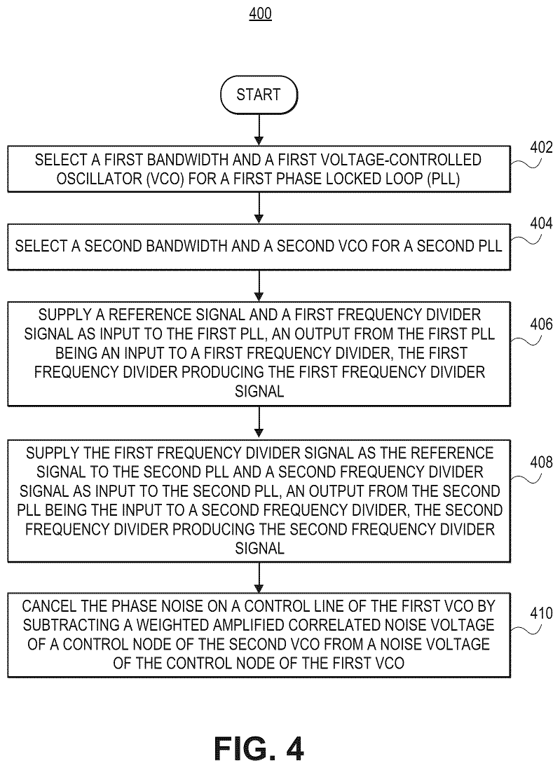

Referring now to FIG. 4, a method 400 for cancelling phase noise includes selecting 402 a first bandwidth and a first voltage-controlled oscillator (VCO) for a first phase locked loop (PLL), selecting 404 a second bandwidth and a second VCO for a second PLL, and supplying 406 a reference signal and a first frequency divider signal as input to the first PLL. An output from the first PLL is an input to a first frequency divider, and the first frequency divider produce the first frequency divider signal. The method includes supplying 408 the first frequency divider signal as the reference signal to the second PLL and a second frequency divider signal as input to the second PLL. An output from the second PLL is the input to a second frequency divider. The second frequency divider produces the second frequency divider signal. The method includes cancelling 410 the phase noise on a control line of the first VCO by subtracting a weighted amplified correlated noise voltage of a control node of the second VCO from a noise voltage of the control node of the first VCO after amplification by an amplifier. The method 400 also can be implemented as in FIGS. 2A-2E where the input signal for the amplifier is the noise across the high pass filter of the second PLL loop filter or directly from the control node the second VCO. When amplifier input is from the node between the resistance and capacitance, it is a high pass configuration for the second loop filter. The output signal of the amplifier could be the control node of the first VCO or the node between the resistor and capacitance in the loop filter of the first PLL.

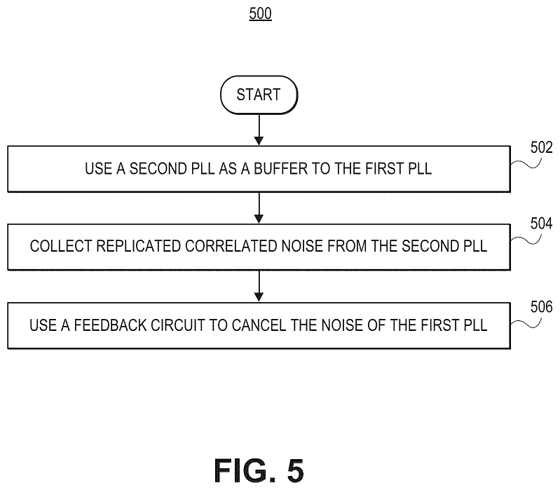

Referring now to FIG. 5, the method 500 for cancelling noise in a first PLL includes using 502 a second PLL as a buffer to the first PLL, collecting 504 replicated correlated noise from the second PLL, and using 506 a feedback circuit to cancel the noise of the first PLL.

Other embodiments of this aspect include corresponding computer systems, apparatus, and computer programs recorded on one or more computer storage devices, each configured to perform the actions of the methods.

As used herein, “electronic communication” means communication of at least a portion of the electronic signals with physical coupling (e.g., “electrical communication” or “electrically coupled”) and/or without physical coupling and via an electromagnetic field (e.g., “inductive communication” or “inductively coupled” or “inductive coupling”). As used herein, “transmit” may include sending at least a portion of the electronic data from one system component to another (e.g., over a network connection). Additionally, as used herein, “data,” “information,” or the like may include encompassing information such as commands, queries, files, messages, data for storage, and the like in digital or any other form.

As used herein, “satisfy,” “meet,” “match,” “associated with”, or similar phrases may include an identical match, a partial match, meeting certain criteria, matching a subset of data, a correlation, satisfying certain criteria, a correspondence, an association, an algorithmic relationship, and/or the like. Similarly, as used herein, “authenticate” or similar terms may include an exact authentication, a partial authentication, authenticating a subset of data, a correspondence, satisfying certain criteria, an association, an algorithmic relationship, and/or the like.

Systems, methods, and computer program products are provided. In the detailed description herein, references to “various embodiments,” “one embodiment,” “an embodiment,” “an example embodiment,” etc. indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to ‘at least one of A, B, and C’ or ‘at least one of A, B, or C’ is used in the claims or specification, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Although the disclosure includes a method, it is contemplated that it may be embodied as computer program instructions on a tangible computer-readable carrier, such as a magnetic or optical memory or a magnetic or optical disk. All structural, chemical, and functional equivalents to the elements of the above-described various embodiments that are known to those of ordinary skill in the art are expressly incorporated herein by reference and are intended to be encompassed by the present claims. Moreover, it is not necessary for a device or method to address each and every problem sought to be solved by the present disclosure for it to be encompassed by the present claims. Furthermore, no element, component, or method step in the present disclosure is intended to be dedicated to the public regardless of whether the element, component, or method step is explicitly recited in the claims. No claim element is intended to invoke 35 U.S.C. § 112(f) unless the element is expressly recited using the phrase “means for” or “step for”. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In re Nuijten to fall outside the scope of patentable subject matter under 35 U.S.C. § 101.

1. A method for cancelling phase noise comprising:
selecting a first bandwidth and a first voltage-controlled oscillator (VCO) for a first phase locked loop (PLL);
selecting a second bandwidth and a second VCO for a second PLL;
supplying a first reference signal and a first frequency divider signal as input to the first PLL, an output from the first PLL being an input to a first frequency divider, the first frequency divider producing the first frequency divider signal;
supplying the first frequency divider signal as a second reference signal to the second PLL and a second frequency divider signal as input to the second PLL, an output from the second PLL being the input to a second frequency divider, the second frequency divider producing the second frequency divider signal; and
cancelling the phase noise on a control node of the first VCO by subtracting a weighted amplified correlated noise voltage of a control node of the second VCO from a noise voltage of the control node of the first VCO after amplification by an amplifier.

2. The method of claim 1, wherein selecting the first bandwidth is based at least on the reference signal, a first loop filter, a signal from the first VCO signal, and a pre-selected application.

3. The method of claim 1, wherein selecting the second bandwidth is based at least on the first bandwidth, a second loop filter, a signal from the second VCO, and a pre-selected application.

4. The method of claim 1, wherein the first PLL locks the first VCO to the first reference signal.

5. The method of claim 1, wherein the first PLL comprises:
a phase detector; and
a low pass filter.

6. The method of claim 1, wherein a signal from the first VCO is divided down using the first frequency divider, the first frequency divider using a division ratio to generate an output frequency from a third frequency reference signal.

7. The method of claim 1, wherein the first PLL bandwidth is selected based on phase locking speed, phase locking stability, and phase noise shaping.

8. The method of claim 1, wherein the control node of the second VCO comprises:
a correlated noise voltage appearing on the control node of the first VCO.

9. A system for cancelling phase noise comprising:
a first phase locked loop (PLL) having a first pre-selected bandwidth, the first PLL receiving a reference signal, the first PLL having a first voltage-controlled oscillator (VCO);
a second PLL having a second pre-selected bandwidth, the second PLL having a second VCO;
a first frequency divider supplying a first frequency divider signal as an input signal to the first PLL and the reference signal to the second PLL, the first frequency divider receiving an output signal from the first PLL as the input signal to the first frequency divider; and
a second frequency divider receiving an output from the second PLL and supplying a second frequency divider signal to the second PLL,
wherein the phase noise is cancelled on a control line of the first VCO by subtracting a correlated noise voltage of a control node of the second VCO from a noise voltage of the control node of the first VCO, the correlated noise voltage of the control node of the second VCO being amplified.

10. The system of claim 9, wherein the first pre-selected bandwidth is selected based at least on the reference signal, a first loop filter, a signal from the first VCO, and a pre-selected application.

11. The system of claim 9, wherein selecting the second pre-selected bandwidth is based at least on the first pre-selected bandwidth, a second loop filter, a signal from the second VCO, and a pre-selected application.

12. The system of claim 9, wherein selecting the second bandwidth is based at least on the first bandwidth, a second loop filter, a signal from the second VCO, and a pre-selected application.

13. The system of claim 9, wherein the first PLL locks the first VCO to the first reference signal.

14. The system of claim 9, wherein the first PLL comprises:
a phase detector; and
a low pass filter.

15. The system of claim 9, wherein a signal from the first VCO is divided down using the first frequency divider, the first frequency divider using a division ratio to generate an output frequency from a third frequency reference signal.

16. The system of claim 9, wherein the first PLL bandwidth is selected based on phase locking speed, phase locking stability, and phase noise shaping.

17. The system of claim 9, wherein the control node of the second VCO comprises:
a correlated noise voltage appearing on the control node of the first VCO.

18. A method for cancelling noise in a first phase locked loop (PLL) comprising:
using a second PLL as a buffer to the first PLL;
collecting replicated correlated noise from the second PLL; and
using a feedback circuit to cancel the noise of the first PLL.

19. The method of claim 18, wherein using the feedback circuit to cancel the noise comprises:
selecting a first bandwidth for a first PLL and a second bandwidth for the second PLL, the first PLL having a first voltage-controlled oscillator (VCO), the second PLL having a second VCO;
supplying a reference signal and a first frequency divider signal as input to the first PLL, an output from the first PLL being an input to a first frequency divider, the first frequency divider producing the first frequency divider signal;
supplying the first frequency divider signal as the reference signal to the second PLL and a second frequency divider signal as input to the second PLL, an output from the second PLL being the input to a second frequency divider, the second frequency divider producing the second frequency divider signal; and
cancelling the noise on a control line of the first VCO by subtracting a correlated noise voltage of a control node of the second VCO from the noise of the control node of the first VCO, the correlated noise voltage of the control node of the second VCO being amplified.

20. The method of claim 18, wherein selecting the first bandwidth is based at least on the reference signal, a first loop filter, a signal from the first VCO, and a pre-selected application.
